(19) United States
(12) Patent Application Publication
(10) Pub. No.: US 2026/0089987 A1
(43) Pub. Date: Mar. 26, 2026

(54) CAPACITOR STRUCTURE, IMAGE SENSOR STRUCTURE, AND METHOD FOR FORMING IMAGE SENSOR STRUCTURE

(71) Applicant: TAIWAN SEMICONDUCTOR MANUFACTURING COMPANY LTD., HSINCHU (TW)

(72) Inventors: MING-HSIEN YANG, TAICHUNG CITY (TW); CHUN-HAO CHOU, TAINAN CITY (TW); CHENG-HAO CHIU, CHANGHUA COUNTY (TW); WEN-CHUNG CHEN, HSINCHU (TW); CHIA-CHAN CHEN, HSINCHU COUNTY (TW); CHIA-YU WEI, TAINAN CITY (TW); KUO-CHENG LEE, TAINAN CITY (TW)

(21) Appl. No.: 18/890,798

(22) Filed: Sep. 20, 2024

(51) Int. Cl. H01L 27/146

(52) U.S. Cl. CPC H10D 1/696; H10D 1/043; H10D 1/716; H10F 39/011; H10F 39/803

(57) ABSTRACT

A capacitor structure, an image sensor structure, and a method for forming an image sensor structure are provided. The capacitor structure includes a capacitor layer. The capacitor layer includes a first conductive layer, a second conductive layer, and a dielectric layer between the first conductive layer and the second conductive layer. S sidewall of the capacitor layer is exposed to an air gap.

### BACKGROUND

Semiconductor image sensors are used to sense radiation, such as light. Complementary metal-oxide-semiconductor (CMOS) image sensors (CIS) are widely used in various applications, such as digital cameras and mobile phone cameras. Such cameras utilize an array of pixels located in a substrate, including photodiodes and transistors that can absorb radiation projected toward the substrate and convert the sensed radiation into electrical signals.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a cross-section of an image sensor structure according to one or more embodiments of the present disclosure.

FIG. 1B is a top view of an image sensor structure according to one or more embodiments of the present disclosure.

FIG. 2A is a cross-section of a capacitor structure according to one or more embodiments of the present disclosure.

FIG. 2B is a top view of a capacitor structure according to one or more embodiments of the present disclosure.

FIG. 2C is a top view of a capacitor structure according to one or more embodiments of the present disclosure.

FIG. 3A is a cross-section of a capacitor structure according to one or more embodiments of the present disclosure.

FIG. 3B is a cross-section of a capacitor structure according to one or more embodiments of the present disclosure.

FIGS. 4A to 4J are cross-sections illustrating a method for forming a capacitor structure according to one or more embodiments of the present disclosure.

FIGS. 5A to 5D are cross-sections illustrating a method for forming a capacitor structure according to one or more embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Embodiments of the present disclosure discuss an image sensor structure including a capacitor structure and a gap adjacent to the capacitor structure. With the design of the gap isolating one or more sidewalls or edges of the capacitor structure from contacting adjacent features, the gap can provide an excellent electrical isolation for the capacitor structure better than that of dielectric materials. Therefore, formation of current leakage paths along the edges of the capacitor structure can be prevented, current leakage can be mitigated or prevented, and thus capacitance lost can be reduced significantly.

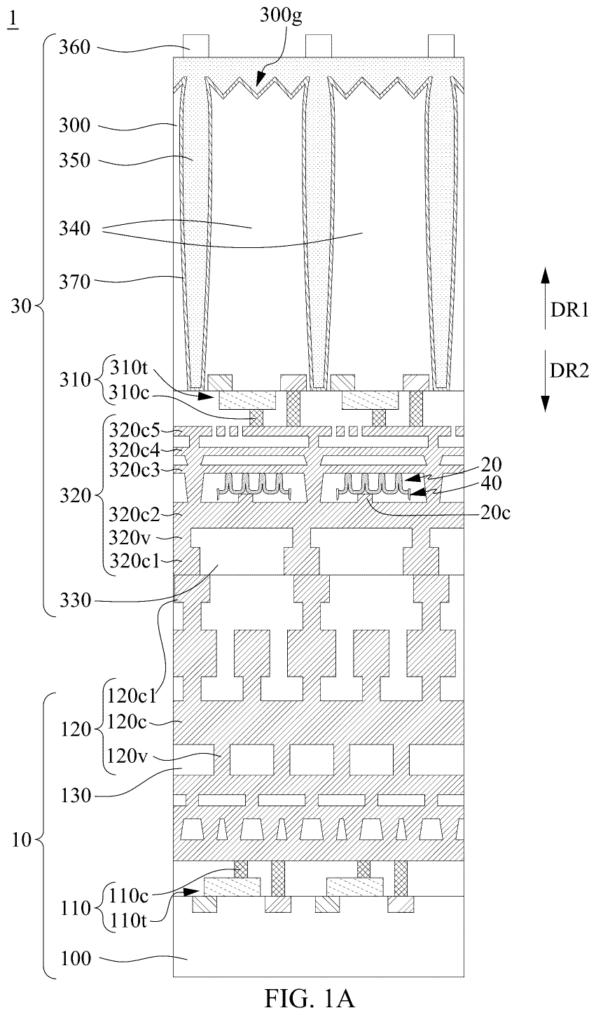

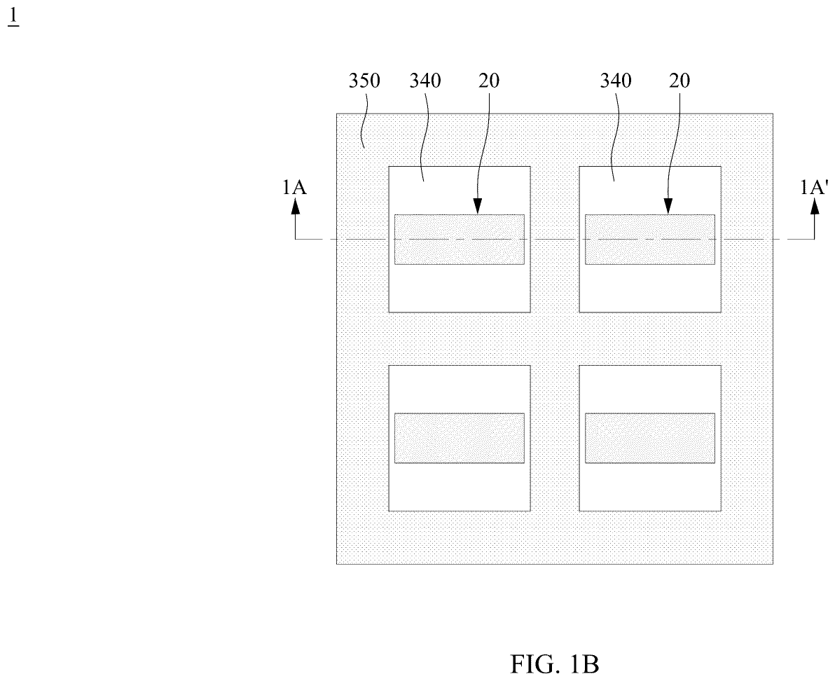

FIG. 1A is a cross-section of an image sensor structure 1 according to one or more embodiments of the present disclosure. FIG. 1B is a top view of an image sensor structure 1 according to one or more embodiments of the present disclosure. In some embodiments, FIG. 1A is a cross-section along a line 1A-1A′ in FIG. 1B. The image sensor structure 1 may include dies 10 and 30. The dies 10 and 30 may be referred to as semiconductor structures or semiconductor devices.

The die 10 may include a semiconductor substrate 100, a circuit layer 110, a redistribution layer (RDL) 120, and a dielectric structure 130. The die 10 may be or include an ASIC.

The semiconductor substrate 100 may be or include silicon (Si), germanium (Ge), and/or compound semiconductor materials such as gallium arsenide (GaAs), but the present disclosure is not limited thereto.

The circuit layer 110 may be disposed over or partially in the semiconductor substrate 100. In some embodiments, the circuit layer 110 includes transistors 110t and connection elements 110c (e.g., conductive vias, conductive pads, conductive pillars or the like) electrically connecting the transistors 110t to the RDL 120. The circuit layer 110 may be or include a logic circuitry, e.g., an image-signal processor.

The RDL 120 may be disposed over the circuit layer 110. In some embodiments, the RDL 120 includes conductive layers 120c and 120c1 and connection elements 120v (e.g., conductive vias, conductive pads, conductive pillars or the like) electrically connected to the conductive layers 120c and 120c1. The conductive layer 120c1 may be referred to as a topmost conductive layer 120c1 that electrically connects to the die 30.

The dielectric structure 130 may encapsulate the circuit layer 110 and the RDL 120. The dielectric structure 130 may include a plurality of dielectric layers. The plurality of dielectric layers may be formed of or include the same or different dielectric materials.

The die 30 may be stacked over the die 10. In some embodiments, the die 30 is bonded to or connected to the die 10. The die 30 may include a semiconductor substrate 300, a circuit layer 310, a RDL 320, a dielectric structure 330, image sensing elements 340, isolation structures 350, a grid structure 360, and a dielectric liner 370. The die 30 may be or include a system-on-chip (SoC). The die 30 may further include a capacitor structure 20. There may be an alignment shift between the dies 10 and 30.

The semiconductor substrate 300 may be a p-type substrate. For example, the semiconductor substrate 300 may be or include a silicon substrate doped with a p-type dopant such as boron. Alternatively, the semiconductor substrate 300 may be an n-type substrate. For example, the semiconductor substrate 300 may be or include a silicon substrate doped with an n-type dopant such as phosphorous or arsenic. The semiconductor substrate 300 may include other elementary semiconductor materials such as germanium. In some embodiments, the semiconductor substrate 300 has a plurality of grooves 300g extending toward the image sensing elements 340. In some embodiments, the grooves 300g form a periodic groove pattern and located at pixel regions (e.g., the image sensing elements 340). The grooves 300g may alter the surface topography of the pixel regions of the semiconductor substrate 300, such that an additional surface area of the pixel regions may be exposed, as compared to a planar surface of the semiconductor substrate 300. In some embodiments, the grooves 300g are configured to provide an increase in exposed areas per horizontal unit area that can be achieved without adjusting the areas of the pixel regions. Increasing the exposed surface area increases the effective light incident area and in turn increases the incident light intensity received by the pixel regions (e.g., the image sensing elements 340). As a result, the quantum efficiency of the pixels is improved.

The circuit layer 310 may be formed over or partially in the semiconductor substrate 300 and within the pixel regions. In some embodiments, the circuit layer 310 includes transistors 310t and connection elements 310c (e.g., conductive vias, conductive pads, conductive pillars or the like) electrically connecting the transistors 310t to the RDL 320. In some embodiments, the transistors 310t may include a transfer transistor, a source-follower transistor, a row select transistor, a reset transistor, or any combination thereof. In some embodiments, the transistors 310t are electrically connected with the image sensing elements 340 to collect (or pick up) electrons generated by incident light (or incident radiation) traveling into the image sensing elements 340 and to convert the electrons into voltage signals.

The RDL 320 may be disposed over the circuit layer 310. In some embodiments, the RDL 320 includes conductive layers 320c1, 320c2, 320c3, 320c4, and 320c5 and connection elements 320v (e.g., conductive vias, conductive pads, conductive pillars or the like) electrically connecting the conductive layers 320c1, 320c2, 320c3, 320c4, and 320c5. The conductive layer 320c1 may be referred to as a bottommost conductive layer that may be electrically connected to or contact the conductive layer 120c1 (or the topmost conductive layer 120c1). The RDL 320 may be misaligned with the RDL 120. In some embodiments, the conductive layer 320c1 is misaligned with the conductive layer 120c1.

The dielectric structure 330 may encapsulate the circuit layer 310 and the RDL 320. The dielectric structure 330 may further encapsulate the capacitor structure 20. The dielectric structure 330 may include a plurality of dielectric layers. The plurality of dielectric layers may be formed of or include the same or different dielectric materials. The dielectric structure 330 may be connected to or contact the dielectric structure 130.

The image sensing elements 340 may be over the semiconductor substrate 100. In some embodiments, the image sensing elements 340 are in the semiconductor substrate 300. In some embodiments, pixel regions may include pixels each with an image sensing element 340. In some embodiments, the image sensing elements 340 may be or include photodetectors, such as photodiodes. In some embodiments, the image sensing elements 340 may be or include doped regions doped with dopants having a doping polarity opposite from that of the semiconductor substrate 300. The image sensing elements 340 may be formed by one or more implantation processes or diffusion processes. The image sensing elements 340 are operable to sense incident light (or incident radiation) that enters the pixel region. The incident light may be visible light. In some embodiments, the incident light may be infrared (IR), ultraviolet (UV), X-ray, microwave, other suitable types of light, or a combination thereof.

The isolation structures 350 may be between the image sensing elements 340 and configured to reflect an incident light received by the image sensor structure 1. In some embodiments, the isolation structures 350 may be or include a deep trench reflective isolation structure.

The grid structure 360 may be over the semiconductor substrate 100. In some embodiments, the grid structure 360 is over the image sensing elements 340 and the isolation structures 350. In some embodiments, the grid structure 360 is aligned with the isolation structures 350. In some embodiments, a width of the grid structure 360 is less than a width of the isolation structures 350. The grid structure 360 may be used to prevent the incident light from entering a neighboring pixel, and thus the crosstalk problems between pixels can be reduced or prevented. In some embodiments, the grid structure 360 is made of or includes a metal material, such as a reflective metal. In some embodiments, the grid structure 360 is made of or includes aluminum, silver, copper, titanium, platinum, tungsten, tantalum, tantalum nitride, other suitable materials, or a combination thereof.

The dielectric liner 370 may be between the image sensing elements 340. The dielectric liner 370 may include silicon oxides or other suitable insulating materials. In some embodiments, the dielectric liner 370 may be or include a high-k dielectric structure. In some embodiments, the dielectric liner 370 includes hafnium oxide (HfO₂), tantalum pentoxide (Ta₂O₅), zirconium dioxide (ZrO₂), aluminum oxide (Al₂O₃), other high-k material, and/or combinations thereof. In some embodiments, the dielectric liner 370 is configured to passivate inner surfaces (or inner walls) of the isolation structures 350. In some embodiments, the dielectric liner 370 is configured to electrically isolate the image sensing elements 340 from one another to reduce electrical crosstalk between the image sensing elements 340.

The capacitor structure 20 may be between the semiconductor substrate 100 and the image sensing elements 340. In some embodiments, the capacitor structure 20 is disposed between and electrically connected to the conductive layers 320c2 and 320c3 of the RDL 320. In some embodiments, one or more sidewalls of the capacitor structure 20 may be spaced apart from the dielectric structure 330 by one or more gaps 40. In some embodiments, the sidewall of the capacitor structure 20 is exposed to the gap 40. In some embodiments, the sidewall of the capacitor structure 20 includes an etched surface formed from a dry etching process for defining the pattern of the capacitor structure 20. In some embodiments, the etched surface of the sidewall of the capacitor structure 20 is exposed to the gap 40 and spaced apart from the dielectric structure 330 by the gap 40. The gap 40 may be or include an air gap or a gap filled with inner gas. In some embodiments, the gap 40 is substantially free of a conductive feature (e.g., a conductive layer, a conductive pattern, a conductive pad, a conductive particle, or the like), an insulation feature (e.g., a dielectric layer, a dielectric particle, or the like), or the combination thereof.

Referring to FIG. 1B, in some embodiments, the capacitor structure 20 includes a plurality of capacitor portions each disposed corresponding to each of the pixel regions (e.g., the image sensing elements 340). In some embodiments, the capacitor portions of the capacitor structure are disposed under openings defined by the isolation structures 350.

According to some embodiments of the present disclosure, the gap 40 isolates the sidewall 21s of the capacitor structure 20 or the capacitor layer 21 from contacting adjacent features. The gap 40 may be a gap filled with air or inner gas, and thus such air gap can provide an excellent electrical isolation better than that of dielectric materials. Therefore, formation of current leakage paths can be prevented, current leakage can be mitigated or prevented, and thus capacitance lost can be reduced significantly.

In addition, when a dry etching process is performed to define edges of the capacitor structure 20, residues of byproducts from the dry etching process may remain on the etched surface, and defects may be formed on the etched surface due to the damages caused by the dry etching process, such that current leakage paths may easily form along the edges (e.g., the etched surface of the sidewall) of the capacitor structure 20 toward adjacent structures (e.g., the dielectric structure 330) that contact the edges of the capacitor structure 20. In contrast, according to some embodiments of the present disclosure, the sidewall (e.g., the etched surface) of the capacitor structure 20 is spaced apart from the dielectric structure 330 by the gap 40. Therefore, the sidewall is free from contacting the dielectric structure 330, and thus the current leakage path formed along the edge (e.g., the etched surface of the sidewall) of the capacitor structure 20 is blocked by the gap 40 and stopped from extending toward the dielectric structure 330. Therefore, current leakage can be mitigated or prevented effectively, and thus capacitance lost can be reduced significantly.

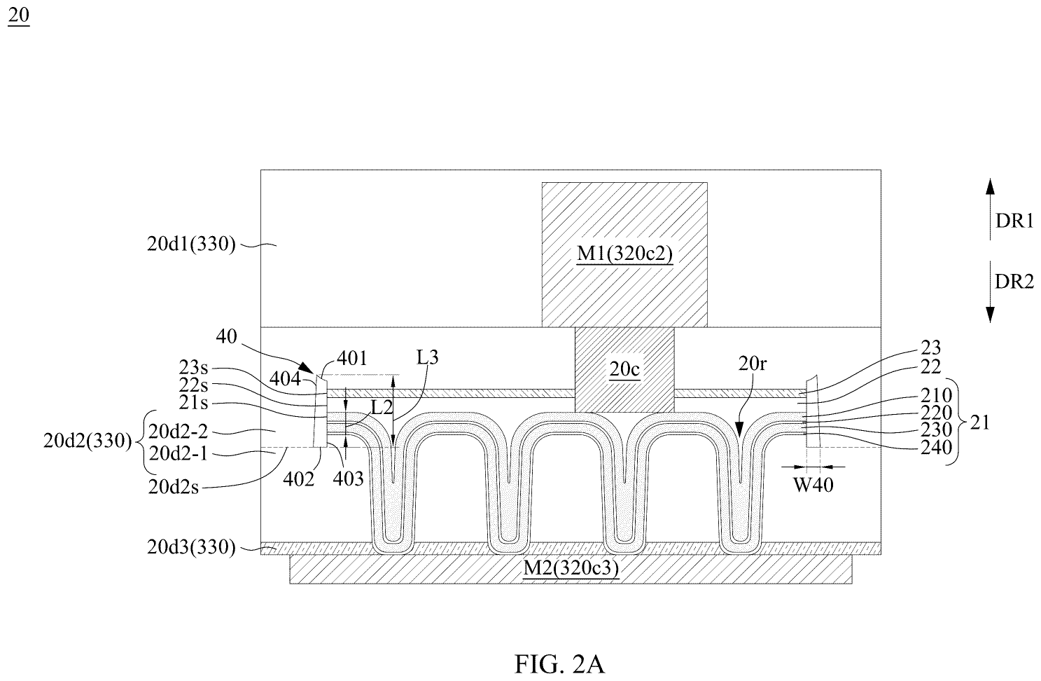

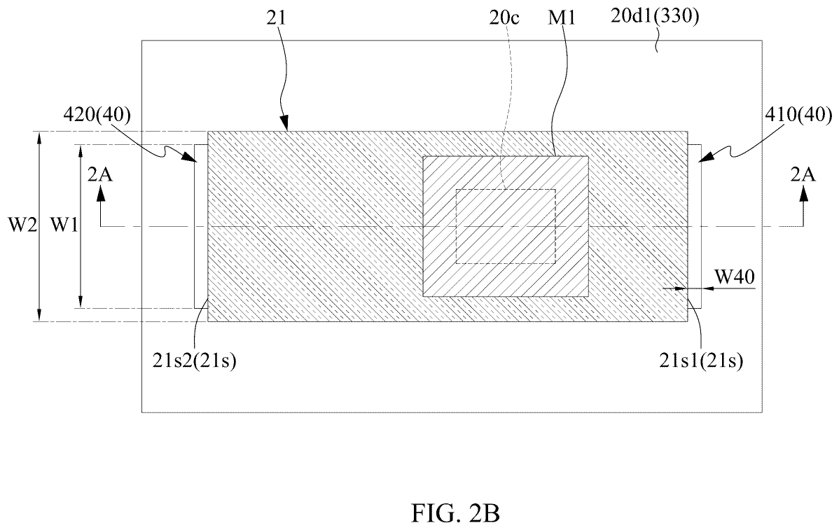

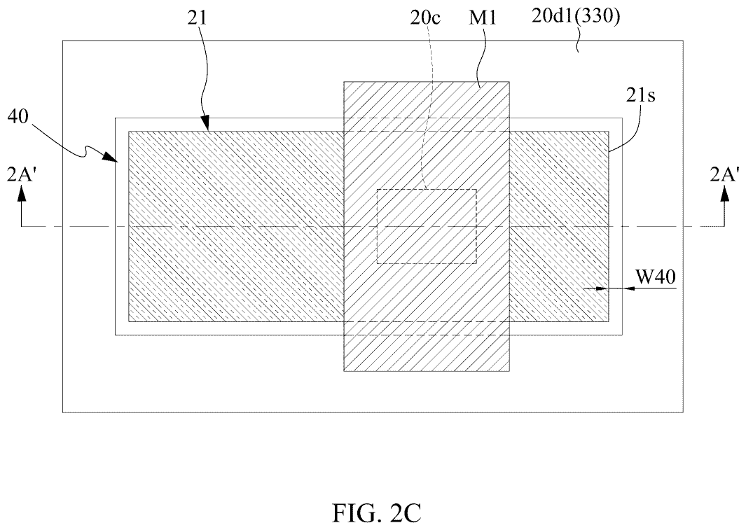

FIG. 2A is a cross-section of a capacitor structure 20 according to one or more embodiments of the present disclosure. FIG. 2B is a top view of a capacitor structure 20 according to one or more embodiments of the present disclosure. In some embodiments, FIG. 2A is a cross-section along a line 2A-2A′ in FIG. 2B.

In some embodiments, the capacitor structure 20 includes a capacitor layer 21, a filling dielectric layer 22, a passivation layer 23, dielectric layers 20d1, 20d2, and 20d3, a conductive element 20c, and conductive layers M1 and M2. Referring to FIG. 1A and FIG. 2A, the dielectric layers 20d1, 20d2, and 20d3 may collectively be referred to as a dielectric structure, e.g., the dielectric structure 330 shown in FIG. 1A, and the conductive layers M1 and M2 may be referred to as the conductive layers 320c2 and 320c3, respectively, shown in FIG. 1A. In some embodiments, referring to FIG. 1A and FIG. 2A, the capacitor layer 21 of the capacitor structure 20 is between the semiconductor substrate 100 and the image sensing elements 340. In some embodiments, one or more sidewalls 21s of the capacitor layer 21 may be spaced apart from the dielectric layer 20d2 (or the dielectric structure 330 as shown in FIG. 1A) by one or more gaps 40.

In some embodiments, the capacitor layer 21 includes conductive layers 210 and 230 (also referred to as “electrodes”), a dielectric layer 220 (also referred to as “an insulator”), and a liner layer 240. In some embodiments, the dielectric layer 220 is between the conductive layers 210 and 230. In some embodiments, the liner layer 240 is disposed under the conductive layer 230 (or the electrode). In some embodiments, the liner layer 240 is between the conductive layer 230 and the dielectric layers 20d2 and 20d3. The liner layer 240 and the conductive layer 230 may collectively form a bottom electrode of the capacitor layer 21 or the capacitor structure 20. The capacitor layer 21 may be referred to as a metal-insulator-metal (MIM) capacitor. The capacitor layer 21 may be referred to as one of the capacitor portions of the capacitor structure 20 illustrated in FIG. 1A and FIG. 1B. In some embodiments, referring to FIG. 1A and FIG. 1B, the capacitor structure 20 may include a plurality of MIM capacitors (e.g., the capacitor layers 21) each corresponding to one of the image sensing elements 340.

In some embodiments, one or more sidewalls of the conductive layer 210 may be substantially aligned with one or more sidewalls of the dielectric layer 220. In some embodiments, one or more sidewalls of the conductive layer 210 may be substantially aligned with one or more sidewalls of the conductive layer 230. In some embodiments, one or more sidewalls of the conductive layer 210 may be substantially aligned with one or more sidewalls of the liner layer 240.

The conductive layers 210 and 230 may include one or more conductive materials, e.g., titanium nitride (TiN). The dielectric layer 220 may be or include a high-k dielectric structure formed of stacked layers ZrO₂/AL₂O₃/ZrO₂ (ZAZ). ZAZ may have the advantageous feature of having a low equivalent oxide thickness, and hence the capacitance value of the resulting capacitor structure 20 is high. The liner layer 240 may be or include a material layer that blocks the material of the conductive layer 230 (or the electrode) from migrating to surrounding structure. The liner layer 240 may be or include, for example, titanium (Ti), tantalum (Ta), titanium nitride (TiN), tantalum nitride (TaN), or a barrier material for the conductive layer 230.

In some embodiments, the filling dielectric layer 22 is over the conductive layer 210 (or the electrode) and filled in one or more recesses 20r defined by the capacitor layer 21. In some embodiments, the filling dielectric layer 22 is filled in the recess 20r defined by the conductive layer 210 (or the electrode). In some embodiments, the filling dielectric layer 22 is spaced apart from the dielectric layer 22d2 by the gap 40. In some embodiments, a sidewall 22s of the filling dielectric layer 22 is substantially aligned with a sidewall 21s of the capacitor layer 21. The filling dielectric layer 22 may include silicon oxide.

In some embodiments, the passivation layer 23 is over the filling dielectric layer 22. In some embodiments, the passivation layer 23 separates the filling dielectric layer 22 from the dielectric layer 20d2. In some embodiments, a sidewall 23s of the passivation layer 23 is substantially aligned with a sidewall 21s of the capacitor layer 21. The passivation layer 23 may include silicon oxynitride.

In some embodiments, the dielectric layer 20d1 is over the dielectric layer 20d2, and the dielectric layer 20d2 is over the dielectric layer 20d3. In some embodiments, the dielectric layer 20d1 encapsulates the conductive layer M1. In some embodiments, the dielectric layer 20d2 encapsulates the capacitor layer 21, the filling dielectric layer 22, the passivation layer 23, and the conductive element 20c. In some embodiments, the dielectric layer 20d2 may include dielectric layers 20d2-1 and 20d2-2 (also referred to as “dielectric sub-layers”). The dielectric layers 20d1, 20d2, and 20d3 may be or include, for example, silicon dioxide, silicon oxynitride, a low-κ dielectric, silicon carbide, silicon nitride, some other dielectric, or any combination of the foregoing. The dielectric layers 20d1, 20d2, and 20d3 may include the same or different dielectric materials. The dielectric layers 20d1 and 20d2 may include silicon oxide, and the dielectric layer 20d3 may include silicon carbide. In some embodiments, an interface 20d2s may be observed between the dielectric layers 20d2-1 and 20d2-2 when the dielectric layers 20d2-1 and 20d2-2 include or are formed of different dielectric materials.

The gap 40 may be embedded in the dielectric layers 20d2 (or the dielectric structure 330 shown in FIG. 1A). The gap 40 may be or include an air gap. The gap 40 may be filled with air or inner gas. The gap 40 may be referred to as an air gap, a void, an empty space, or the like. In some embodiments, a width W40 of the gap 40 is less than 10 nm, for example, less than 8 nm, 6 nm, 4 nm, or 2 nm. The gap 40 may have or be defined by surfaces 401, 402, 403, and 404 (also referred to as “inner surfaces” or “inner walls”). In some embodiments, the dielectric layer 20d2 (or the dielectric structure 330 shown in FIG. 1A) defines the surfaces 401, 402, 404, and a portion of the surface 403 of the gap 40. In some embodiments, sidewalls of the capacitor layer 21, the filling dielectric layer 22, and the passivation layer 23 define a portion of the surface 403 of the gap 40.

In some embodiments, an upper surface (e.g., the surface 401) of the gap 40 includes a curved surface. In some embodiments, an upper surface (e.g., the surface 401) of the gap 40 includes a tilted or inclined curved surface. In some embodiments, an upper surface (e.g., the surface 401) of the gap 40 is convex toward an inner portion of the gap 40. In some embodiments, a bottom surface (e.g., the surface 402) of the gap 40 is substantially aligned with the interface 20d2s. The surface 401 may be substantially inclined with respect to the surface 402. In some embodiments, side surfaces (e.g., the surfaces 403 and 404) are non-parallel to each other. In some embodiments, the side surface (e.g., the surface 403) is substantially perpendicular to a top surface of the dielectric layer 20d3. In some embodiments, a side surface (e.g., the surface 404) of the gap 40 is inclined with respect to a top surface of the dielectric layer 20d3.

In some embodiments, the gap 40 (or the air gap) tapers in a direction DR1 substantially parallel to the sidewall 21s of the capacitor layer 21. In some embodiments, the gap 40 (or the air gap) tapers in a direction DR1 extending substantially from the conductive layer M2 toward the conductive layer M1. In some embodiments, referring to FIG. 1A and FIG. 2A, the gap 40 (or the air gap) tapers in a direction DR1 extending substantially from the semiconductor substrate 100 toward the image sensing elements 340. In some embodiments, the gap 40 (or the air gap) has a length L1 extending in a direction DR1 substantially parallel to a sidewall 21s of the capacitor layer 21. In some embodiments, the length L1 of the gap 40 is greater than a length L2 of the sidewall 21s of the capacitor layer 21. In some embodiments, the gap 40 extends towards the dielectric layer 20d1 (or the image sensing elements 340 shown in FIG. 1A) and protruding beyond the passivation layer 23. In some embodiments, the gap 40 extends towards the dielectric layer 20d3 (or the die 10 shown in FIG. 1A) and protruding beyond the passivation layer 23.

In some embodiments, sidewalls of the conductive layers 210 and 230 (or the electrodes) and the dielectric layer 220 (or the insulator) are spaced apart from the dielectric layer 20d2 (or the dielectric structure 330 shown in FIG. 1A) by the gap 40. In some embodiments, one or more sidewalls 21s of the capacitor layer 21 are exposed to the gap 40. In some embodiments, sidewalls of the filling dielectric layer 22 and the liner layer 240 are spaced apart from the dielectric layer 20d2 (or the dielectric structure 330 shown in FIG. 1A) by the gap 40. In some embodiments, one or more sidewalls 22s of the filling dielectric layer 22 are exposed to the gap 40. In some embodiments, one or more sidewalls 23s of the passivation layer 23 may be spaced apart from the dielectric layer 20d2 (or the dielectric structure 330 shown in FIG. 1A) by the gap 40. In some embodiments, one or more sidewalls 23s of the passivation layer 23 are exposed to the gap 40.

The conductive layer M1 (also referred to as the conductive layer 320c2 shown in FIG. 1A) may be over and electrically connected to the conductive element 20c. The dielectric layer 20d1 (or the dielectric structure 330 shown in FIG. 1A) may encapsulate the conductive layer M1. The capacitor layer 21 (or the conductive layer 210) may be electrically connected to the conductive layer M1 through the conductive element 20c. The conductive layer M1 may be or include a metal layer, and the conductive element 20c may be or include a conductive via or a conductive pillar. The metal layer, the conductive via, and the conductive pillar may independently be formed of or include, such as, gold (Au), silver (Ag), aluminum (Al), nickel (Ni), palladium (Pd), copper (Cu) or alloys thereof.

The conductive layer M2 (also referred to as the conductive layer 320c3 shown in FIG. 1A) may be disposed on the dielectric layer 20d3. The conductive layer M2 may be electrically connected to the capacitor layer 21. The conductive layer M2 may be or include a metal layer, and the metal layer may be formed of or include, such as, Au, Ag, Al, Ni, Pd, Cu or alloys thereof.

Referring to FIG. 2B, the gap 40 (or the air gap) includes gap portions 410 and 420 that are spaced apart from each other. In some embodiments, the sidewall 21s of the capacitor layer 21 includes a wall 21s1 exposed to the gap portion 410 and a wall 21s2 opposite to the wall 21s1 and exposed to the gap portion 420. In some embodiments, a width W2 of the gap 40 (or the gap portions 410 and 420) may be substantially equal to or less than a width W1 of the sidewall 21s (or the walls 21s1 and 21s2) of the capacitor layer 21 from a top view perspective.

According to some embodiments of the present disclosure, the width W40 of the gap 40 is relatively small (e.g., less than 8 nm, 6 nm, 4 nm, or 2 nm). In the process for forming the capacitor structure 20, after the gap 40 is formed between the sidewall of the capacitor layer 21 and a portion of the dielectric layer 20d2, another portion of the dielectric layer 20d2 is then formed over the gap 40 and the passivation layer 23 to form the dielectric layer 20d2. With the relatively small width W40 of the gap 40, it can increase the difficulty of filling the abovementioned another portion of the dielectric layer 20d2 into the gap 40. Therefore, the gap 40 can be prevented from being filled with a substantial or physical layer, and thus the etched surface of the sidewall can be exposed to the air gap without contacting the dielectric layer 20d2. Therefore, current leakage can be mitigated or prevented effectively, and thus capacitance lost can be reduced significantly.

In addition, according to some embodiments of the present disclosure, the gap 40 tapers toward the conductive layer M1. With the design of the width W40 of the gap 40 decreasing upwards, it can further increase the difficulty of filling the abovementioned another portion of the dielectric layer 20d2 into the gap 40. Therefore, the gap 40 can be prevented from being filled with a substantial or physical layer, and thus the etched surface of the sidewall can be exposed to the air gap without contacting the dielectric layer 20d2. Therefore, current leakage can be mitigated or prevented more effectively, and thus capacitance lost can be reduced significantly.

FIG. 2C is a top view of a capacitor structure according to one or more embodiments of the present disclosure. In some embodiments, FIG. 2A is a cross-section along a line 2A-2A′ in FIG. 2C.

In some embodiments, the sidewall 21s of the capacitor layer 21 surrounds a periphery of the capacitor layer 21, and the gap 40 (or the air gap) surrounds the sidewall 21s.

In some embodiments, the conductive layer M1 (or the metal layer) is electrically connected to the capacitor layer 21. In some embodiments, referring to FIG. 2A and FIG. 2C, the conductive layer M1 overlaps the gap 40 from a top view perspective and is spaced apart from the gap 40.

According to some embodiments of the present disclosure, the gap 40 surrounds the sidewall 21s of the capacitor layer 21. Therefore, the etched surface that surrounds the periphery of the capacitor layer 21 can be exposed to the gap 40 and spaced apart from the dielectric layer 20d2. Therefore, formation of current leakage paths around the periphery or the surrounding edge of the capacitor layer 21 (or the capacitor structure 20) can be prevented effectively, current leakage can be prevented, and thus capacitance lost can be further reduced significantly.

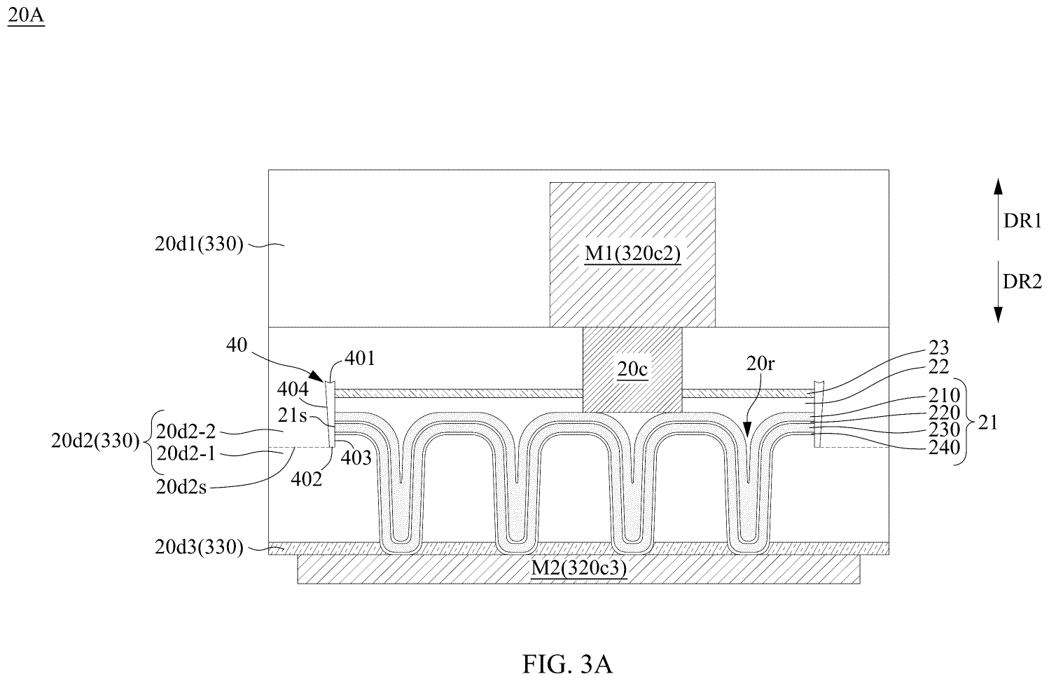

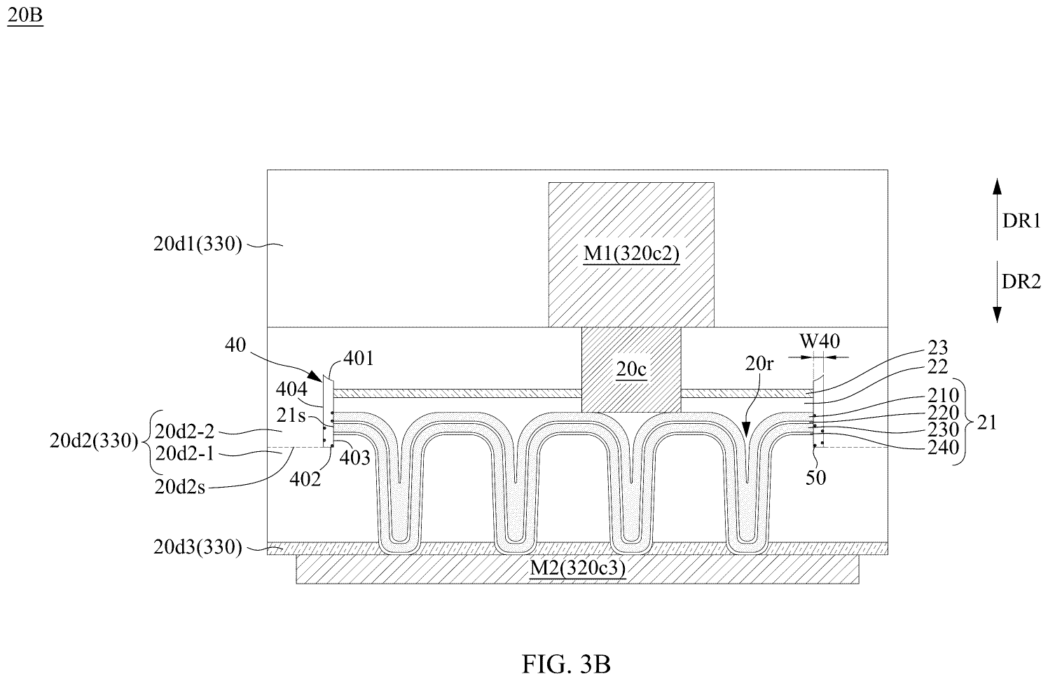

FIG. 3A is a cross-section of a capacitor structure 20A according to one or more embodiments of the present disclosure. The capacitor structure 20A is similar to the capacitor structure 20 in many aspects, and thus descriptions of these aspects are not repeated for brevity.

In some embodiments, the gap 40 (or the air gap) tapers in a direction DR2 substantially parallel to the sidewall 21s of the capacitor layer 21. In some embodiments, the gap 40 (or the air gap) tapers in a direction DR2 extending substantially from the conductive layer M1 toward the conductive layer M2. In some embodiments, referring to FIG. 1A and FIG. 3A, the gap 40 (or the air gap) tapers in a direction DR2 extending substantially from the image sensing elements 340 toward the semiconductor substrate 100. The direction DR2 may be substantially opposite to the direction DR1.

In some embodiments, an upper surface (e.g., the surface 401) of the gap 40 includes a curved surface. In some embodiments, an upper surface (e.g., the surface 401) of the gap 40 is convex toward an inner portion of the gap 40.

FIG. 3B is a cross-section of a capacitor structure 20B according to one or more embodiments of the present disclosure. The capacitor structure 20B is similar to the capacitor structure 20 in many aspects, and thus descriptions of these aspects are not repeated for brevity.

In some embodiments, the capacitor structure 20B further includes a plurality of particles 50 in the gap 40. The particles 50 may be formed of or include a material the same as one or more materials of the capacitor layer 21, the filling dielectric layer 22, a passivation layer 23, a dielectric layer 20d2, or a combination thereof. In some embodiments, the particles 50 include a conductive material including TiN and/or Ta, a dielectric material including silicon oxide, silicon nitride, and/or silicon oxynitride, or a combination thereof. In some embodiments, a width W40 of the gap 40 is less than 10 nm, and a size of the particles 50 is less than 1 nm. In some embodiments, a ratio of the size of the particles 50 with respect to the width W40 of the gap 40 is less than 0.1. In some embodiments, the surfaces 403 and 404 are substantially parallel to each other.

According to some embodiments of the present disclosure, the particles 50 having a size of less than 1 nm may remain in the gap 40. By allowing the relatively small particles 50 to remain in the gap 40, the particles 50 are small enough not to induce the formation of the current leakage paths, and an additional cleaning process for removing the particles 50 can be omitted in the process for forming the capacitor structure 20. Therefore, the process can be simplified, the cost can be reduced, and the current leakage can still be mitigated or prevented.

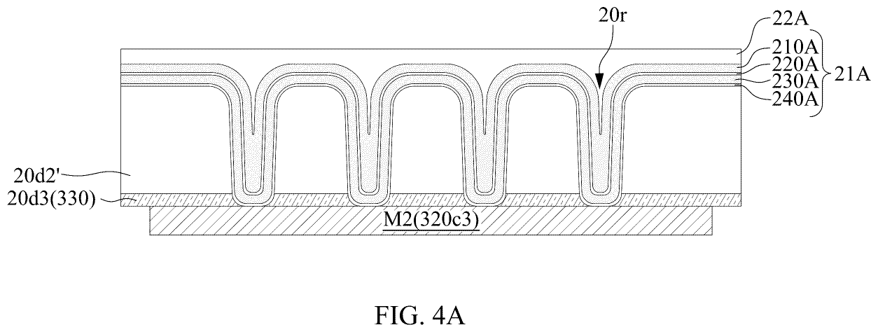

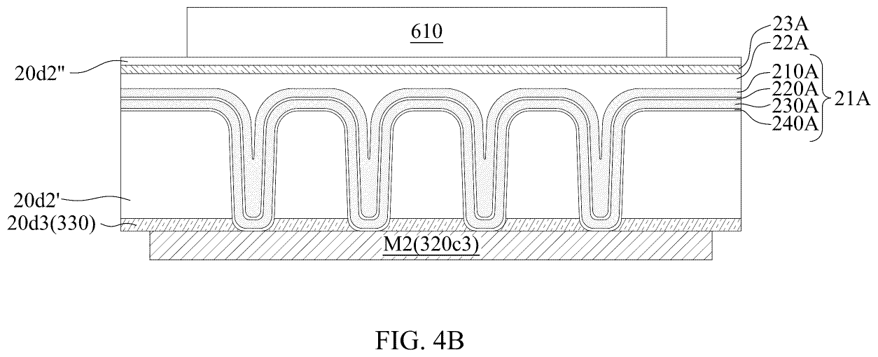

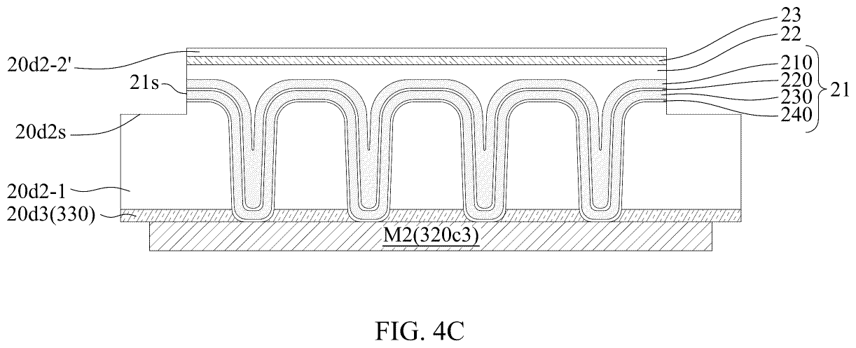

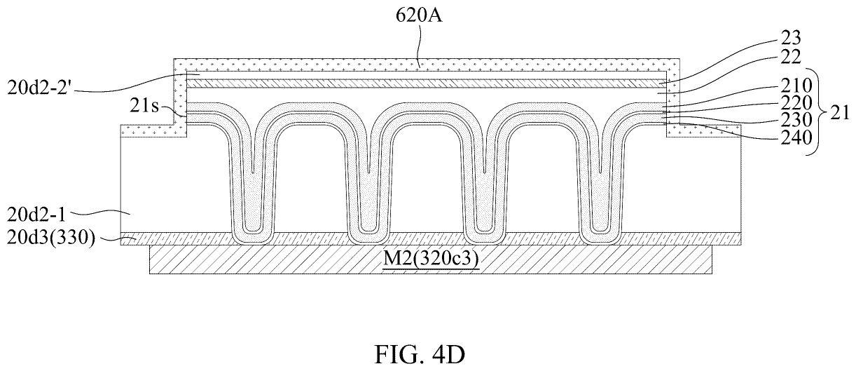

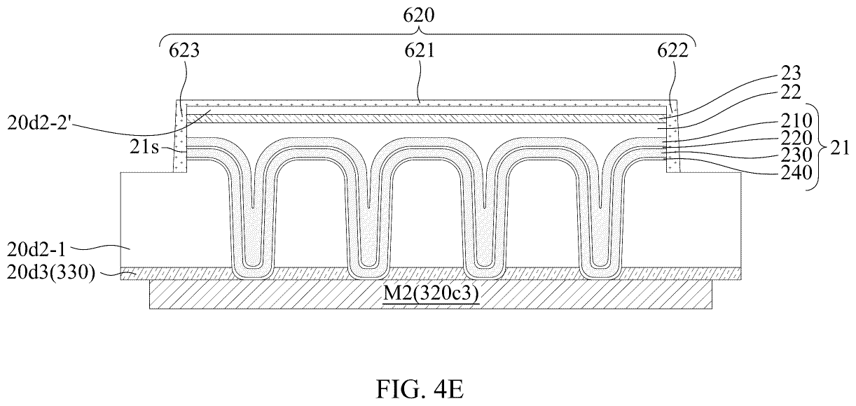

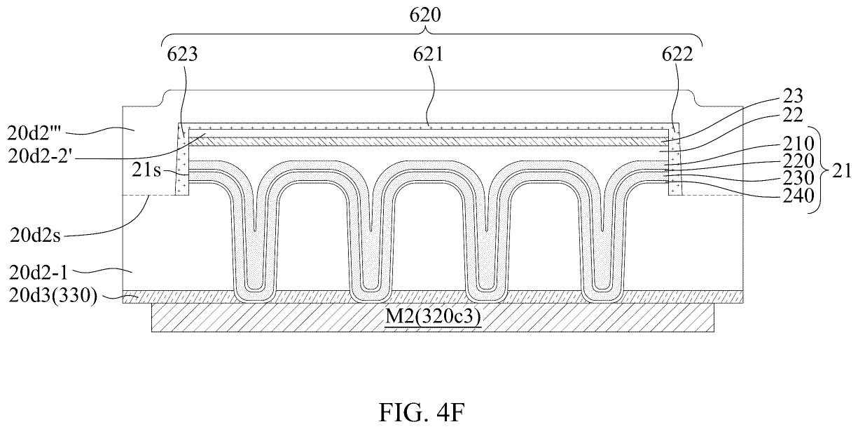

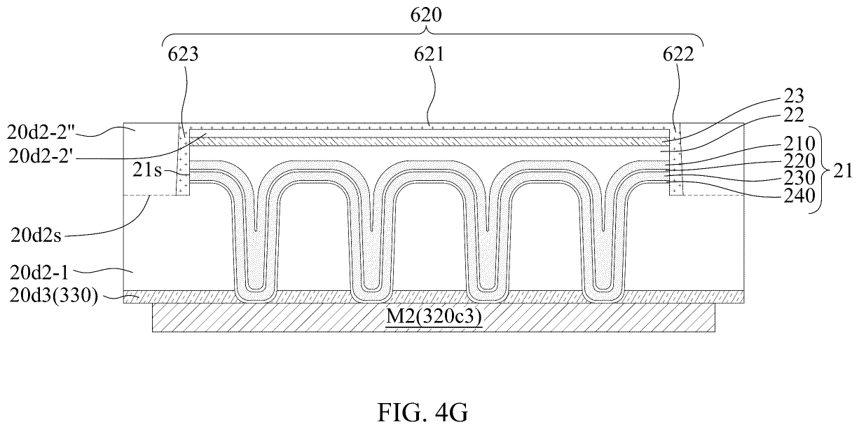

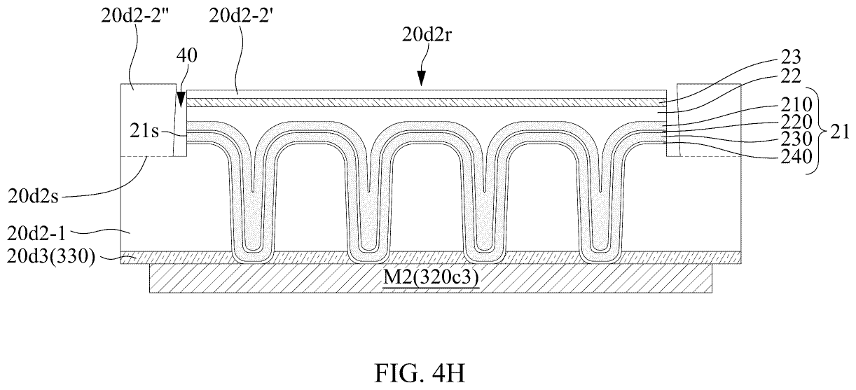

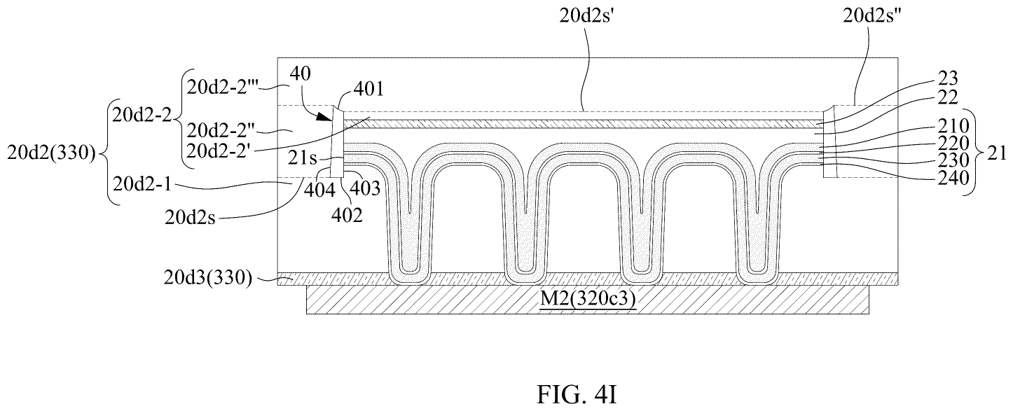

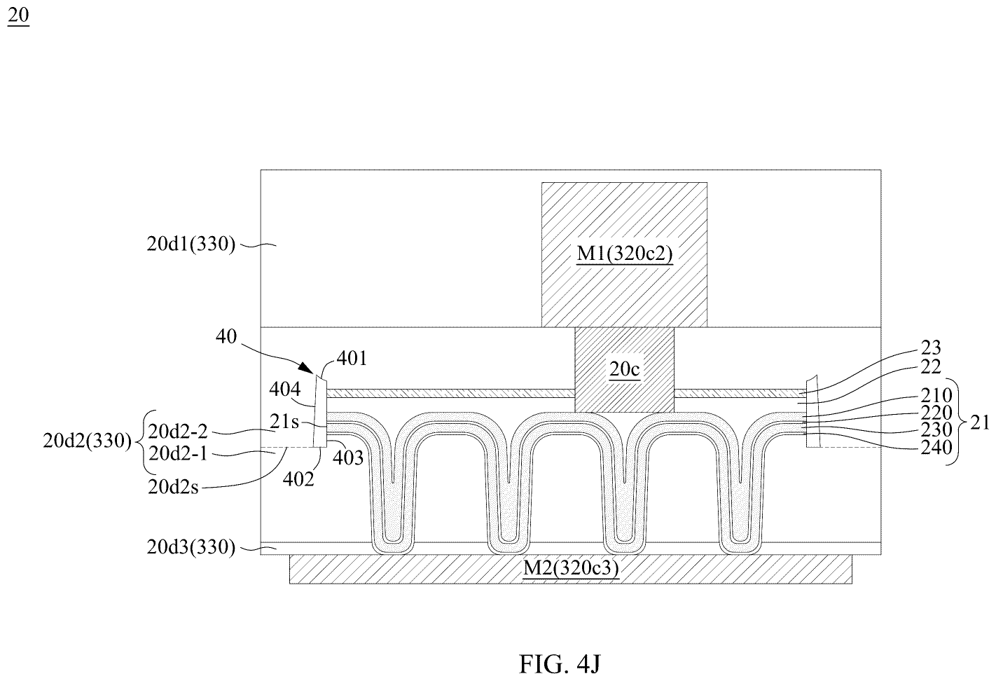

FIGS. 4A to 4J are cross-sections illustrating a method for forming a capacitor structure 20 according to one or more embodiments of the present disclosure. In some embodiments, referring to FIG. 1A and FIGS. 4A to 4J, a method for forming an image sensor structure 1 may be provided.

Referring to FIG. 4A, a capacitor layer 21A may be formed over a conductive layer M2. Referring to FIG. 1A and FIG. 4A, the capacitor layer 21A may be formed over a semiconductor substrate 100. In some embodiments, forming the capacitor layer 21A includes forming a conductive layer 210A (or a first electrode layer) over the semiconductor substrate 100, forming a dielectric layer 220A over the conductive layer 210A (or the first electrode layer), and forming a conductive layer 230A (or a second electrode layer) over the dielectric layer 220A. In some embodiments, forming the capacitor layer 21A further includes forming a liner layer 240A over the semiconductor substrate 100, and the conductive layer 210A (or the first electrode layer) is formed on the liner layer 240A.

In some embodiments, referring to FIG. 4A, the capacitor layer 21A may be formed on and partially within a dielectric layer 20d3, which is formed on the conductive layer M2. In some embodiments, a filling dielectric layer 22A is formed on the capacitor layer 21A and partially filled in recesses 20r of the capacitor layer 21A. In some embodiments, a dielectric layer 20d2′ is formed on the dielectric layer 20d3 and encapsulating the capacitor layer 21A and the filling dielectric layer 22A.

Referring to FIG. 4B, a passivation layer 23A may be formed on the filling dielectric layer 22A, a dielectric layer 20d2″ (also referred to as a buffer layer) may be formed on the passivation layer 23A, and a sacrificial pattern 610 may be formed on the dielectric layer 20d2″. In some embodiments, the sacrificial pattern 610 includes a material different from that of the dielectric layers 20d2″, the passivation layer 23A, the filling dielectric layer 22A, and the capacitor layer 21A. The sacrificial pattern 610 may be or include silicon nitride. The sacrificial pattern 610 serves to define a pattern, a coverage, a shape, or a range of the capacitor structure 20 or the capacitor layer 21 to be formed.

Referring to FIG. 4C, the capacitor layer 21A, the filling dielectric layer 22A, and the passivation layer 23A may be partially removed by etching to form the capacitor layer 21, the filling dielectric layer 22, and the passivation layer 23 and expose sidewalls of the capacitor layer 21, the filling dielectric layer 22, and the passivation layer 23. In some embodiments, the dielectric layer 20d2′ is partially removed by etching to form the dielectric layer 20d2-1 having a top surface (i.e., the interface 20d2s) exposed by the capacitor layer 21. In some embodiments, the dielectric layer 20d2″ is partially removed by etching to form the dielectric layer 20d2-2′. In some embodiments, the capacitor layer 21A, the filling dielectric layer 22A, the passivation layer 23A, and the dielectric layers 20d2′ and 20d2″ may be etched according to the sacrificial pattern 610. As such, the pattern of the capacitor layer 21 may be defined by the etching process according to the sacrificial pattern 610. In some embodiments, the conductive layers 210A and 230A (or the electrodes) and the dielectric layer 220A may be partially removed by etching to expose sidewalls of the conductive layers 210 and 230 and the dielectric layer 220. In some embodiments, the liner layer 240A may be partially removed by etching to expose a sidewall of the liner layer 240. In some embodiments, the dielectric layer 20d2″ may be partially removed by etching to expose a sidewall of the dielectric layer 20d2-2′. The etching process may be or include a dry etching process. In some embodiments, the sacrificial pattern 610 is removed after the etching process.

Referring to FIG. 4D, a spacer layer 620A may be formed on the exposed sidewalls of the capacitor layer 21, the filling dielectric layer 22, and the passivation layer 23. In some embodiments, the spacer layer 620A is formed on the exposed sidewall and the top surface of the dielectric layer 20d2-2′. In some embodiments, the spacer layer 620A is formed on the exposed sidewalls of the conductive layers 210 and 230, the dielectric layer 220, and the liner layer 240. In some embodiments, the spacer layer 620A is formed on the top surface the conductive layer 210. In some embodiments, the spacer layer 620A is formed on the top surface the dielectric layer 20d2-1. The spacer layer 620A may be or include silicon nitride.

Referring to FIG. 4E, the spacer layer 620A may be partially removed to form a spacer layer 620 including a spacer film 621 and spacer walls 622 and 623. The spacer layer 620A may be partially removed by etching, e.g., a dry etching process. In some embodiments, the spacer film 621 covers the top surface of the dielectric layer 20d2-2′, and the spacer walls 622 and 623 cover the exposed sidewalls of the capacitor layer 21, the filling dielectric layer 22, the passivation layer 23, and the dielectric layers 20d2-2′ and 20d2-1. In some embodiments, the spacer walls 622 and 623 cover the etched surfaces of the exposed sidewalls. In some embodiments, the spacer walls 622 and 623 include tapered profiles. The spacer walls 622 and 623 may taper upwards toward the spacer film 6

Referring to FIG. 4F, a dielectric layer 20d2′″ may be formed over the spacer layer 620. The dielectric layer 20d2′″ may be referred to as a portion of a dielectric layer 20d2 which will be formed subsequently. The dielectric layer 20d2′″ may be referred to as a portion of the dielectric structure 330 shown in FIG. 1A. In some embodiments, the dielectric layer 20d2′″ is on and covering a top surface of the spacer layer 620. In some embodiments, the dielectric layer 20d2′″ covers the spacer film 621 and the spacer walls 622 and 632. The dielectric layer 20d2′″ may be formed on the top surface (e.g., the interface 20d2s) of the dielectric layer 20d2-1. The dielectric layer 20d2′″ may be or include silicon oxide.

Referring to FIG. 4G, the dielectric layer 20d2′″ may be partially removed to expose a portion of the spacer layer 620. In some embodiments, the dielectric layer 20d2′″ is partially removed to expose top surfaces of the spacer film 621 and the spacer walls 622 and 632. In some embodiments, a portion of the spacer layer 620 is partially removed along with the removal of the dielectric layer 20d2′″. In some embodiments, the dielectric layer 20d2′″ and the spacer layer 620 are partially removed by a grinding process or a polishing process, e.g., a chemical mechanical polishing (CMP) process.

Referring to FIG. 4H, the spacer layer 620 may be removed to form one or more gaps 40. In some embodiments, the spacer layer 620 is removed by etching, e.g., a wet etching process. In some embodiments, the spacer walls 622 and 623 are removed to form the gap 40 between the dielectric layer 20d2-2′″ and the exposed sidewalls of the capacitor layer 21, the filling dielectric layer 22, and the passivation layer 23. In some embodiments, the spacer walls 622 and 623 are removed to form the gap 40 between the dielectric layer 20d2-2′″ and the etched surfaces of the exposed sidewalls. In some embodiments, the spacer film 621 is removed to form a recess 20d2r over the dielectric layer 20d2-2′. The spacer layer 620 may include silicon nitride, and the etchant of the wet etching process may include phosphoric acid (H₃PO₄). The gap 40 may have a tapered profile that is substantially the same as that of the spacer walls 622 and 623.

Referring to FIG. 4I, a dielectric layer 20d2 (or the dielectric structure 330 shown in FIG. 1A) may be formed to encapsulate the capacitor layer 21. In some embodiments, a dielectric layer 20d2-2′″ is formed over the dielectric layers 20d2-2′ and 20d2-2″. In some embodiments, the dielectric layer 20d2-2′″ partially extends into the gap 40 to form a curved surface 401 convex toward an inner portion of the gap 40. In some embodiments, the dielectric layers 20d2-2′, 20d2-2″, and 20d2-2′″ collectively form a dielectric layer 20d2-2, and the dielectric layers 20d2-1 and 20d2-2 collectively form a dielectric layer 20d2 (or the dielectric structure 330 shown in FIG. 1A). In some embodiments, an interface 20d2s′ may be observed between the dielectric layers 20d2-2′ and 20d2-2′″ when the dielectric layers 20d2-2′ and 20d2-2′″ include or are formed of different dielectric materials. In some embodiments, an interface 20d2s′″ may be observed between the dielectric layers 20d2-2′″ and 20d2-2′″ when the dielectric layers 20d2-2′″ and 20d2-2′″ include or are formed of different dielectric materials. In some embodiments, the dielectric layer 20d2 encapsulates the capacitor layer 21, and a sidewall 21s of the capacitor layer 21 is spaced apart from the dielectric layer 20d2 (or the dielectric structure 330 shown in FIG. 1A) by the gap 40. In some embodiments, due to the step difference in the top surfaces of the dielectric layers 20d2-2′ and 20d2-2″, the as-formed surface 401 is tilted or inclined with respect to the surface 402.

Referring to FIG. 4J, a conductive element 20c may be formed to penetrate the dielectric layer 20d2, the passivation layer 23, and the filling dielectric layer 22 to contact and electrically connect to the capacitor layer 21, a conductive layer M2 may be formed on and electrically connected to the conductive element 20c, and a dielectric layer 20d1 may be formed over the dielectric layer 20d2 and encapsulating the conductive layer M2. As such, the capacitor structure 20 may be formed.

In some embodiments, referring to FIG. 1A and FIG. 4J, a die 10 including a semiconductor substrate 100, a circuit layer 110, an RDL 120, and a dielectric structure 130 may be provided. In some embodiments, the circuit layer 110 is formed on and partially within the semiconductor substrate 100, and the RDL 120 including conductive layers 120c and 120c1 and connection elements 120v are formed over the semiconductor substrate 100. In some embodiments, the dielectric structure 130 may be formed to encapsulate the circuit layer 110 and the RDL 120.

In some embodiments, referring to FIG. 1A and FIG. 4J, a die 30 including a semiconductor substrate 300, a circuit layer 310, a RDL 320, a dielectric structure 330, image sensing elements 340, isolation structures 350, a grid structure 360, a dielectric liner 370, and the capacitor structure 20 (or the capacitor layers 21) may be provided. In some embodiments, the image sensing elements 340, the isolation structures 350, and the dielectric liner 370 are formed in the semiconductor substrate 300. In some embodiments, the circuit layer 310 is formed on and partially within the semiconductor substrate 300. In some embodiments, the RDL 320 including conductive layers 320c1, 320c2, 320c3, 320c4, and 320c5 and connection elements 320v are formed over the semiconductor substrate 300. In some embodiments, the capacitor structure 20 (or the capacitor layers 21) may be formed between the conductive layer 320c2 (or the conductive layer M1 shown in FIG. 4J) and the conductive layer 320c3 (or the conductive layer M2 shown in FIG. 4J), and a dielectric structure 330 may be formed to encapsulate the RDL 320 and the capacitor structure 20.

In some embodiments, referring to FIG. 1A and FIG. 4J, the die 10 is connected to or bonded to the die 30. In some embodiments, the image sensing elements 340 may be formed over the capacitor layer 21. As such, an image sensor structure 1 may be formed.

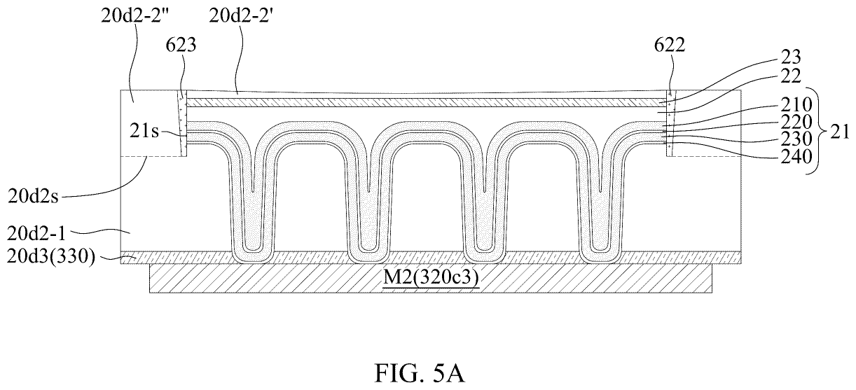

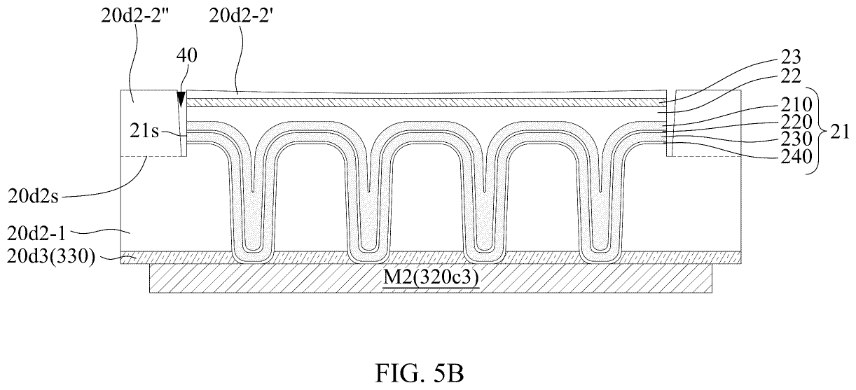

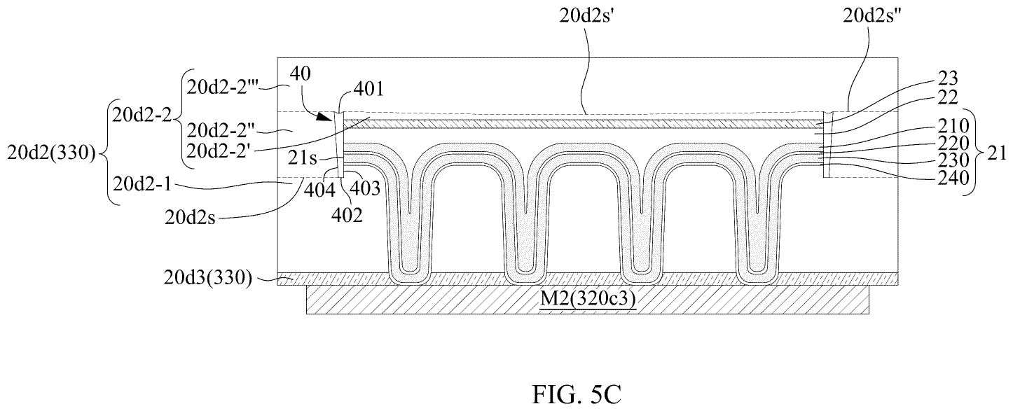

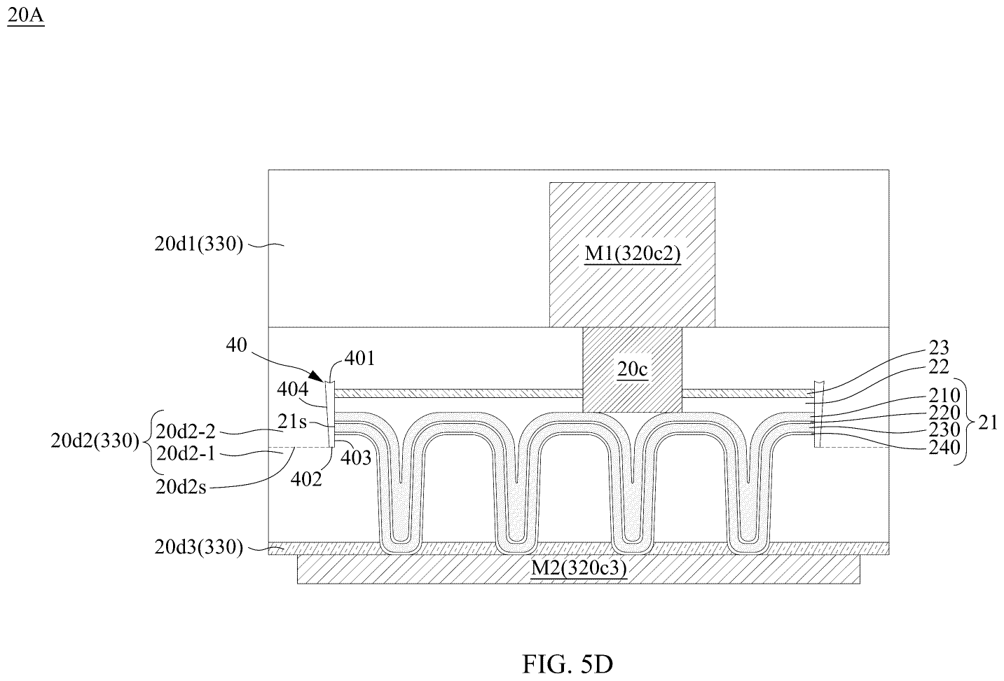

FIGS. 5A to 5D are cross-sections illustrating a method for forming a capacitor structure 20A according to one or more embodiments of the present disclosure.

Referring to FIG. 5A, operations similar to those illustrated in FIGS. 4A-4F may be performed to form a spacer layer 620 on the exposed sidewalls of the conductive layers 210 and 230, the dielectric layer 220, and the liner layer 240, and operations similar to those illustrated in FIGS. 4A-4F may be performed to form a dielectric layer 20d2′″ over the spacer layer 620. Next, in some embodiments, the dielectric layer 20d2′″ and the spacer layer 620 may be partially removed to expose a top surface of the dielectric layer 20d2-2′ and the spacer walls 622 and 623. In some embodiments, the spacer film 621 is removed, and the dielectric layer 20d2-2′ is partially removed to form a concave top surface. In some embodiments, a top surface of the dielectric layer 20d2-2′ is exposed by the spacer layer (or the spacer walls 622 and 623). In some embodiments, the dielectric layers 20d2′″ and 20d2-2′ are partially removed by a grinding process or a polishing process, e.g., a chemical mechanical polishing (CMP) process. In some embodiments, the spacer film 621 is removed by a grinding process or a polishing process, e.g., a CMP process. The spacer film 621 may be removed by the same process for partially removing the dielectric layers 20d2′″ and 20d2-2′.

Referring to FIG. 5B, the spacer walls 622 and 623 may be removed to form one or more gaps 40. In some embodiments, the spacer walls 622 and 623 are removed by etching, e.g., a wet etching process. In some embodiments, the spacer walls 622 and 623 are removed to form the gap 40 between the dielectric layer 20d2-2′″ and the exposed sidewalls of the capacitor layer 21, the filling dielectric layer 22, and the passivation layer 23. In some embodiments, the spacer walls 622 and 623 are removed to form the gap 40 between the dielectric layer 20d2-2′″ and the etched surfaces of the exposed sidewalls. The gap 40 may have a tapered profile that is substantially the same as that of the spacer walls 622 and 623.

Referring to FIG. 5C, operations similar to those illustrated in FIG. 4I may be performed to form the dielectric layer 20d2 that encapsulates the capacitor layer 21, and a sidewall 21s of the capacitor layer 21 is spaced apart from the dielectric layer 20d2 (or the dielectric structure 330 shown in FIG. 1A) by the gap 40.

Referring to FIG. 5D, operations similar to those illustrated in FIG. 4J may be performed to form a conductive element 20c that penetrates the dielectric layer 20d2, the passivation layer 23, and the filling dielectric layer 22 to electrically connect to and contact the capacitor layer 21, a conductive layer M2 on and electrically connected to the conductive element 20c, and a dielectric layer 20d1 over the dielectric layer 20d2 and encapsulating the conductive layer M2. As such, the capacitor structure 20A may be formed.

In some embodiments, referring to FIG. 1A and FIG. 5D, a die 10 including a semiconductor substrate 100, a circuit layer 110, an RDL 120, and a dielectric structure 130 may be provided, a die 30 including a semiconductor substrate 300, a circuit layer 310, a RDL 320, a dielectric structure 330, image sensing elements 340, isolation structures 350, a grid structure 360, a dielectric liner 370, and the capacitor structure 20A (or the capacitor layers 21) may be provided, and the die 10 may be connected to or bonded to the die 30. As such, an image sensor structure similar to that illustrated in FIG. 1A and including the capacitor structure 20A may be formed.

Some embodiments of the present disclosure provide a capacitor structure. The capacitor structure includes a capacitor layer. The capacitor layer includes a first conductive layer, a second conductive layer, and a dielectric layer between the first conductive layer and the second conductive layer. S sidewall of the capacitor layer is exposed to an air gap.

Some embodiments of the present disclosure provide an image sensor structure. The image sensor structure includes a semiconductor substrate, a plurality of image sensing elements, a capacitor layer, and a dielectric structure. The image sensing elements are over the semiconductor substrate. The capacitor layer is between the semiconductor substrate and the image sensing elements. The dielectric structure encapsulates the capacitor layer, and a sidewall of the capacitor layer is spaced apart from the dielectric structure by a gap.

Some embodiments of the present disclosure provide a method for forming an image sensor structure. The method includes following operations: forming a capacitor layer over a semiconductor substrate; forming a dielectric structure encapsulating the capacitor layer, wherein a sidewall of the capacitor layer is spaced apart from the dielectric structure by a gap; and forming a plurality of image sensing elements over the capacitor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A capacitor structure, comprising:
a capacitor layer comprising:
a first conductive layer and a second conductive layer; and
a dielectric layer between the first conductive layer and the second conductive layer;
wherein a sidewall of the capacitor layer is exposed to an air gap.

2. The capacitor structure of claim 1, further comprising a filling dielectric layer over the first conductive layer and filled in a recess defined by the capacitor layer, wherein a sidewall of the filling dielectric layer is substantially aligned with the sidewall of the capacitor layer and exposed to the air gap.

3. The capacitor structure of claim 2, further comprising a passivation layer over the filling dielectric layer, wherein a sidewall of the passivation layer is substantially aligned with the sidewall of the capacitor layer and exposed to the air gap.

4. The capacitor structure of claim 1, wherein the air gap tapers in a direction substantially parallel to the sidewall of the capacitor layer.

5. The capacitor structure of claim 1, wherein the air gap comprises a first gap portion and a second gap portion spaced apart from the first gap portion, and the sidewall comprises a first wall exposed to the first gap portion and a second wall opposite to the first wall and exposed to the second gap portion.

6. The capacitor structure of claim 1, wherein the sidewall surrounds a periphery of the capacitor layer, and the air gap surrounds the sidewall.

7. The capacitor structure of claim 1, further comprising a plurality of particles in the air gap, wherein a width of the air gap is less than 10 nm, and a size of the particles is less than 1 nm.

8. An image sensor structure, comprising:
a semiconductor substrate;
a plurality of image sensing elements over the semiconductor substrate;
a capacitor layer between the semiconductor substrate and the image sensing elements; and
a dielectric structure encapsulating the capacitor layer, wherein a sidewall of the capacitor layer is spaced apart from the dielectric structure by a gap.

9. The image sensor structure of claim 8, wherein the dielectric structure defines an upper surface of the gap that is convex toward an inner portion of the gap.

10. The image sensor structure of claim 8, wherein the gap tapers in a direction substantially from the semiconductor substrate toward the image sensing elements.

11. The image sensor structure of claim 8, further comprising a metal layer electrically connected to the capacitor layer, wherein the metal layer overlaps the gap from a top view perspective and is spaced apart from the gap.

12. The image sensor structure of claim 8, wherein the capacitor layer comprises a first electrode, a second electrode, and an insulator between the first electrode and the second electrode, and sidewalls of the first electrode, the second electrode, and the insulator are spaced apart from the dielectric structure by the gap.

13. The image sensor structure of claim 12, further comprising a filling dielectric layer filled in a recess defined by the first electrode and a liner layer disposed under the second electrode, and sidewalls of the filling dielectric layer and the liner layer are spaced apart from the dielectric structure by the gap.

14. The image sensor structure of claim 8, wherein the gap has a length extending in a direction substantially parallel to the sidewall, and the length of the gap is greater than a length of the sidewall.

15. A method for forming an image sensor structure, comprising:
forming a capacitor layer over a semiconductor substrate;
forming a dielectric structure encapsulating the capacitor layer, wherein a sidewall of the capacitor layer is spaced apart from the dielectric structure by a gap; and
forming a plurality of image sensing elements over the capacitor layer.

16. The method of claim 15, wherein forming the capacitor layer comprises:
forming a first electrode over the semiconductor substrate;
forming a dielectric layer over the first electrode;
forming a second electrode over the dielectric layer; and
partially removing the first electrode, the dielectric layer, and the second electrode by etching to expose sidewalls of the first electrode, the dielectric layer, and the second electrode.

17. The method of claim 16, wherein forming the dielectric structure comprises:
forming a spacer layer on the exposed sidewalls of the first electrode, the dielectric layer, and the second electrode;
forming a portion of the dielectric structure over the spacer layer; and
removing the spacer layer by etching to form the gap between the dielectric structure and the exposed sidewalls of the first electrode, the dielectric layer, and the second electrode.

18. The method of claim 17, wherein forming the dielectric structure further comprises:
forming the spacer layer on a top surface the first electrode;
forming the portion of the dielectric structure on and covering a top surface of the spacer layer; and
partially removing the dielectric structure to expose a portion of the spacer layer prior to removing the spacer layer.

19. The method of claim 16, wherein forming the capacitor layer further comprises:
forming a liner layer over the semiconductor substrate, wherein the first electrode is formed on the liner layer; and
partially removing the liner layer to expose a sidewall of the liner layer.

20. The method of claim 19, wherein forming the dielectric structure comprises:
forming a spacer layer on the exposed sidewalls of the first electrode, the dielectric layer, the second electrode, and the liner layer;
forming a portion of the dielectric structure over the spacer layer;
exposing a top surface of the portion of the dielectric structure from the spacer layer; and
removing the spacer layer by etching to form the gap between the sidewall of the capacitor layer and the dielectric structure.
